(19) United States
(12) Patent Application Publication
(10) Pub. No.: US 2012/0094440 A1
(43) Pub. Date: Apr. 19, 2012

(54) METHOD OF DIE BONDING ONTO DISPENSED ADHESIVES

(76) Inventors: Kwok Kee CHUNG, Kwai Chung (HK); Kui Kam LAM, Kwai Chung (HK); Yen Hsi TANG, Kwai Chung (HK); Kwok Kiu CHAN, Kwai Chung (HK)

(21) Appl. No.: 12/905,413

(22) Filed: Oct. 15, 2010

(51) Int. Cl. H01L 21/50

(52) U.S. Cl. 438/118; 257/E21.499

(57) ABSTRACT

A method of bonding semiconductor dice onto a substrate first uses an optical assembly to perform pattern recognition of a die bonding section of the substrate in which multiple die pads are located so as to identify positions of the multiple die pads simultaneously during such pattern recognition step. After pattern recognition of the said die bonding section, an adhesive is dispensed with an adhesive dispenser onto at least one of the die pads located in the die bonding section. While the adhesive dispenser is dispensing the adhesive to further die pads located in the die bonding section, a pick-and-place arm concurrently bonds a die onto each die pad where the adhesive has already been dispensed.

### FIELD OF THE INVENTION

The invention relates to a die bonding method for electronic devices, and in particular, to a die bonding method which effectively bonds a die to a substrate before curing of an adhesive dispensed onto the substrate occurs.

### BACKGROUND AND PRIOR ART

During the production of semiconductor dice or chips, many semiconductor dice are formed together on a single wafer. The wafer is then cut to separate the individual dice. Each of these semiconductor dice should then be individually mounted onto a support surface for further processing by utilizing a die bonding process. Thereafter, electrical connections are created between the dice and external devices, and the dice are later encapsulated with a plastic compound to protect them from the environment.

In prior art die bonders utilized in the said die bonding process, each individual die is usually picked up from the wafer by a bond arm and then transported to a bonding site for bonding onto a substrate. The substrate has an adhesive dispensed thereon to secure attachment of the die onto the substrate. In order to achieve a high throughput to increase the units processed per hour or UPH, an adhesive dispenser is located upstream from the bonding site and the dispensing and die attachment operations are carried out sequentially. However, certain adhesives may react very quickly with the surrounding air such that the adhesives are cured and solidify before a die can be attached.

FIG. 1 is a plan view of two panels of substrates 100,102 arranged on a conveyor for carrying out a conventional die bonding method. Two adhesive dispensers 104, 106 are located above a substrate 102 and are spaced apart along its length. The substrate 100, 102 may comprise a leadframe or a printed circuit board and has die pads onto which semiconductor dice 110 may be mounted. A die bonding site 108 where die attachment takes place is located downstream of the adhesive dispensers 104, 106 along the indexing direction of the substrates 100, 102. In this die bonder setup, an adhesive dispenser optical system carries out pattern recognition of the position of the substrate 100, 102 for dispensing adhesive and a die attachment optical system carries out pattern recognition of the substrate 100, 102 for die attachment. There is also a substrate conveying device which is operative to index and transfer the substrate which has received dispensed adhesive towards the bonding site 108 for die attachment by a pick-and-place die attachment device. Although the dispensing and die attachment processes can take place simultaneously at separate locations, the time taken between dispensing and die attachment is relatively long when the density of die pads 112 on a substrate 100, 102 is high. The adhesive might be cured and solidify before the die 110 can be attached thereto.

FIG. 2 is a plan view of another conventional die bonding method. The setup of the apparatus is similar to the conventional die bonding setup illustrated in FIG. 1. However, the left and right adhesive dispensers 104, 106 and the bonding site 108 are arranged as close as possible to one another along the indexing direction of the substrates 100, 102 as permitted by the spatial requirements of the adhesive dispensing optical system and die attachment optical system.

As the distance between the dispensers 104, 106 and the bonding site 108 is reduced, the risk of the adhesive curing before a die 110 is attached to it may be reduced. Although this arrangement permits adhesive dispensation and die attachment to occur simultaneously at separate locations that are closer to each other along the same column of die pads 112 on the substrate 100, 102, the time taken for a die 110 which has received dispensed adhesive to reach the bonding site 108 is increased when the number of rows of die pads 112 on the substrate 100, 102 increases. The time to complete die bonding is very much dependent on the number of rows present in the substrate 100, 102. Therefore, when the number of rows of die pads 112 on the substrate increases, occurrences of the dispensed adhesive solidifying before die attachment may also increase. It would therefore be desirable to implement a die bonder capable of bonding a die to a substrate swiftly before the adhesive cures and solidifies.

### SUMMARY OF THE INVENTION

It is thus an object of the invention to seek to provide a die bonder that is operative to dispense an adhesive onto a substrate and to attach a die to the substrate thereafter within a shorter time as compared to the prior art, before the adhesive cures.

Accordingly, the invention provides a method of bonding semiconductor dice onto a substrate, comprising the steps of using an optical assembly to perform pattern recognition of a die bonding section of the substrate in which multiple die pads are located so as to identify positions of the multiple die pads simultaneously during such pattern recognition step; after pattern recognition of the said die bonding section, dispensing an adhesive with an adhesive dispenser onto at least one of the die pads located in the die bonding section; and while dispensing the adhesive to further die pads located in the die bonding section, concurrently bonding a die with a pick-and-place arm onto each die pad where the adhesive has already been dispensed.

It will be convenient to hereinafter describe the invention in greater detail by reference to the accompanying drawings. The particularity of the drawings and the related description is not to be understood as superseding the generality of the broad identification of the invention as defined by the claims.

### BRIEF DESCRIPTION OF THE DRAWINGS

The present invention will be readily appreciated by reference to the detailed description of one preferred embodiment of the invention when considered with the accompanying drawings, in which:

FIG. 1 is a plan view of two panels of substrates arranged on a conveyor for carrying out a conventional die bonding method;

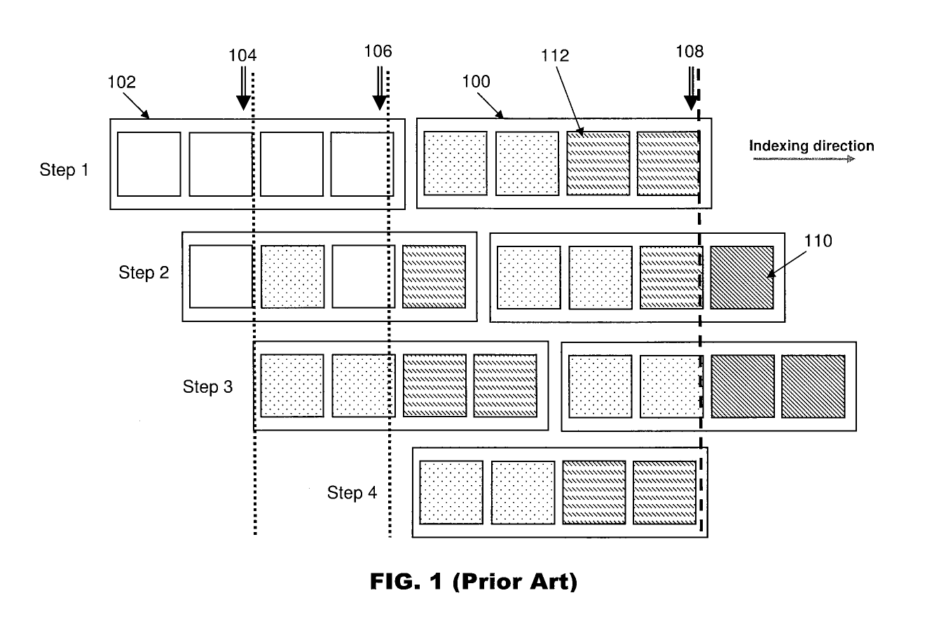

FIG. 2 is a plan view of another conventional die bonding method;

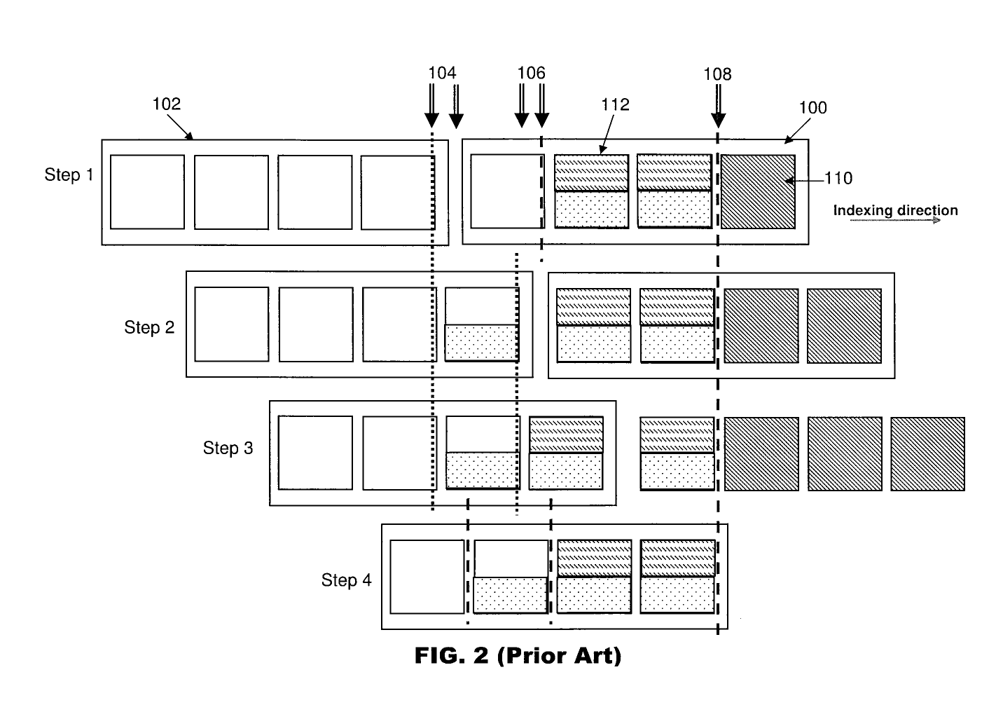

FIG. 3 is a plan view of a die bonder according to the preferred embodiment of the invention;

FIG. 4 is a schematic plan view of a substrate undergoing pattern recognition by a placement pattern recognition system before receiving an adhesive;

FIG. 5 is a schematic plan view illustrating a sequence by which a substrate receives adhesive after pattern recognition of several columns of the die pads has been completed;

FIG. 6 is a schematic plan view of the substrate wherein the steps of adhesive dispensation and die attachment are carried out concurrently; and

FIG. 7 is a schematic plan view of the substrate illustrating completion of adhesive dispensation over multiple columns of die pads.

### DETAILED DESCRIPTION OF THE PREFERRED EMBODIMENT OF THE INVENTION

The preferred embodiment of the present invention will be described hereinafter with reference to the accompanying drawings.

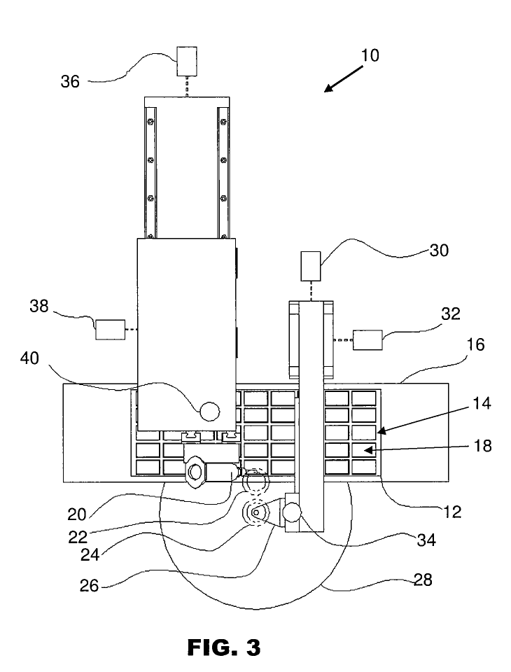

FIG. 3 is a plan view of a die bonder 10 according to the preferred embodiment of the invention. The die bonder 10 may be an epoxy die bonder 10 which includes an epoxy dispenser 20 or jet for dispensing epoxy as an adhesive to bond dice 18 to a leadframe 12 located at a workstation 16. The die bonder 10 further comprises an optical assembly for pattern recognition of the leadframe 12 for the purpose of aligning the epoxy dispenser 20 with die pads 14 on the leadframe 12 so as to deposit epoxy accurately onto the leadframe 12. The optical assembly comprises both a placement pattern recognition system 22 and a pick-up pattern recognition system 24 which are incorporated into the optical assembly. Additionally, there is a pick-and-place arm 26 which is positioned adjacent to the epoxy dispenser 20 for picking up a die 18 from a wafer 28 and placing the die 18 onto the desired die pad 14. The XYZ directional movements of the pick-and-place arm 26 are controllable by a pick-and-place X-axis controller 30, a pick-and-place Y-axis controller 32 and a pick-and-place Z-axis controller 34. A substrate conveyor (not shown) indexes the leadframe 12 relative to the pick-and-place arm 26. XYZ directional movements of the epoxy dispenser 20 are controlled by a dispenser X-axis controller 36, a dispenser Y-axis controller 38 and a dispenser Z-axis controller 40.

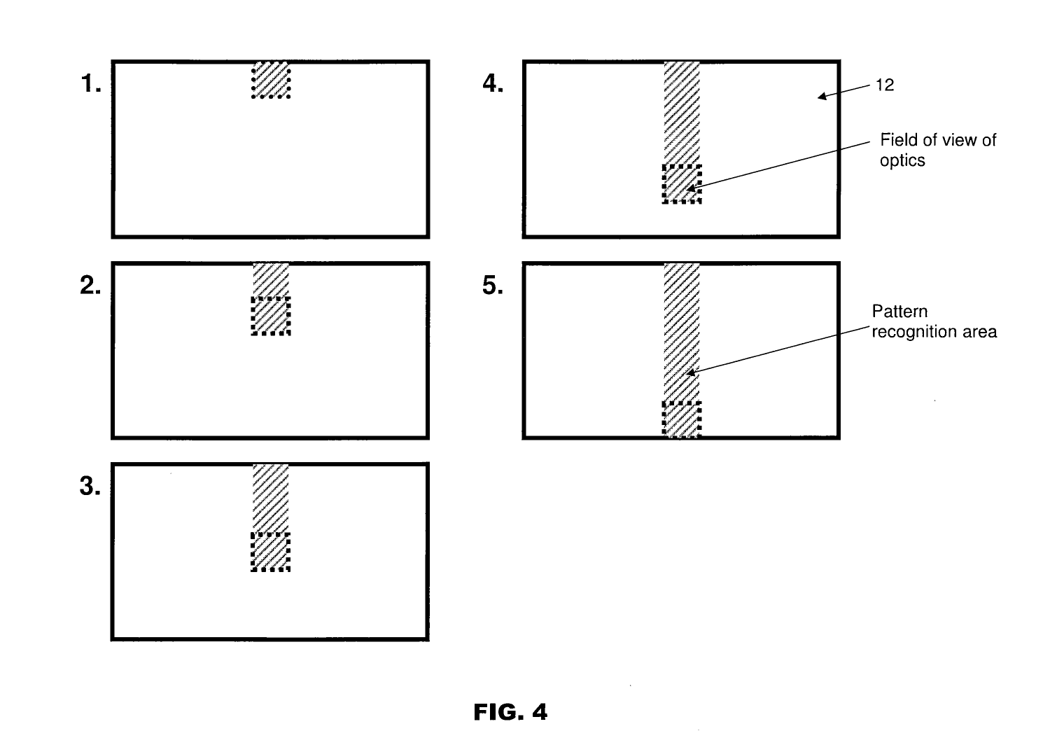

FIG. 4 is a schematic plan view of a leadframe 12 undergoing pattern recognition by a placement pattern recognition system 22 of the optical assembly before receiving an adhesive. The substrate or leadframe 12 is transferred from a substrate-supplying unit and is placed onto a substrate conveyor device. The placement pattern recognition system 22 is positioned above a first edge of the leadframe 12 to view several columns of the die pads 14. The placement pattern recognition system 22 is moved parallel to a column of die pads 14 from the first edge of the leadframe 12 towards a second edge opposite to the first edge to perform pattern recognition of a die bonding section of the leadframe 12 in which multiple die pads 14 are located so as to view and identify the multiple die pads 14 simultaneously. Thus, the placement pattern recognition system 22 may be operable to view and scan multiple columns of the die pads 14 on the leadframe 12 at the same time. Preferably, the die pads 14 in the die bonding section form a portion of all the die pads 14 located on the leadframe 12, so as to increase resolution of images captured by the placement pattern recognition system 22. The die bonding section may comprise multiple columns and rows of die pads 14 or a single column containing multiple rows of die pads 14.

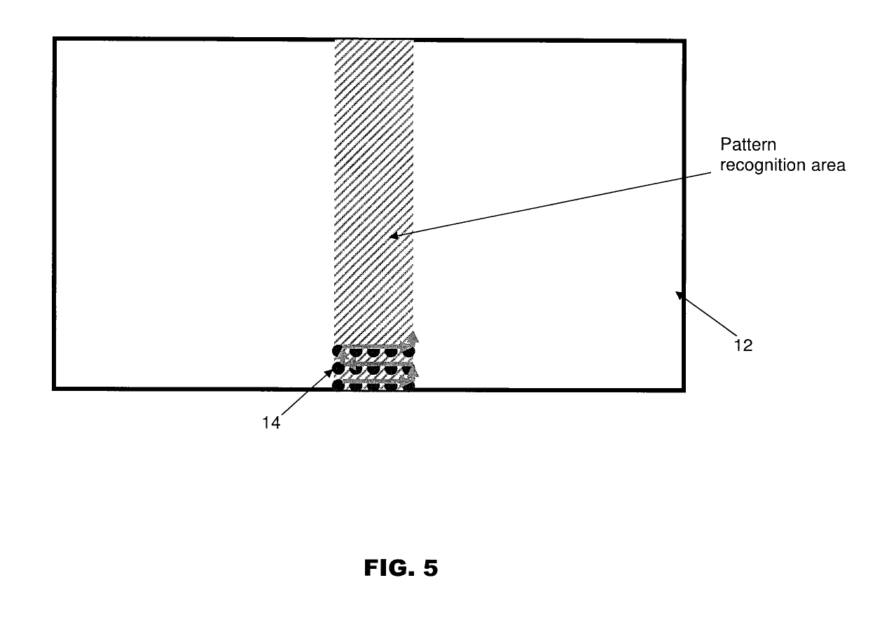

FIG. 5 is a schematic plan view illustrating a sequence by which a leadframe 12 receives adhesive after pattern recognition of several columns of the die pads 14 at the die bonding section has been completed. An adhesive dispenser such as an epoxy dispenser 20 dispenses adhesive onto at least one of the die pads 14 located in the die bonding section by moving the dispenser 20 starting from a pick-up location which is over a first row of the die pads 14 from the second edge of the leadframe 12 towards the first edge of the leadframe 12. The epoxy dispenser 20 may either dispense adhesive to a single column containing multiple rows of die pads 14 a row at a time, or sequentially dispense adhesive to separate columns of die pads 14 a row at a time.

Whether the dispensation is conducted onto only one column or several columns of die pads 14 at a time, dispensation continues row-by-row along the areas that have been scanned by the placement pattern recognition system 22. Optionally, inspection of the dispensed adhesive may be carried out using the placement pattern recognition system 22 or an additional separate camera (not shown) before bonding a die onto the die pad 14 that has received the adhesive.

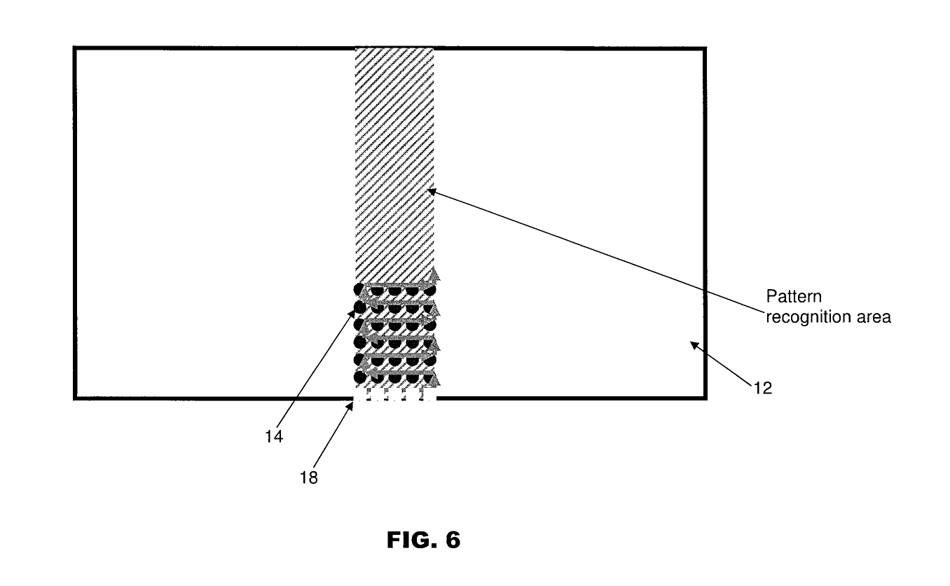

FIG. 6 is a schematic plan view of the substrate wherein the steps of adhesive dispensation and die attachment are carried out concurrently. The pick-and-place arm 26 attaches the dice 18 one at a time to each die pad 14 in a same sequence as a sequence by which the adhesive has been dispensed onto the die pads 14 starting from the first row of die pads 14 at the second edge. At the same time, the epoxy dispenser 20 continues to dispense epoxy to further die pads 14 located in the die bonding section towards the first edge of the leadframe 12. During adhesive dispensation, the pick-and-place arm 26 may bond dice 18 onto positions of the multiple die pads 14 using positional information which had already been obtained by the optical assembly during the pattern recognition step described above so that a separate optical device is not necessary for further pre-bond pattern recognition as required in the prior art. Optionally, inspection of the dice 18 after bonding the dice 18 to check bonding accuracy may also be carried out using the placement pattern recognition system 22 or an additional separate camera (not shown).

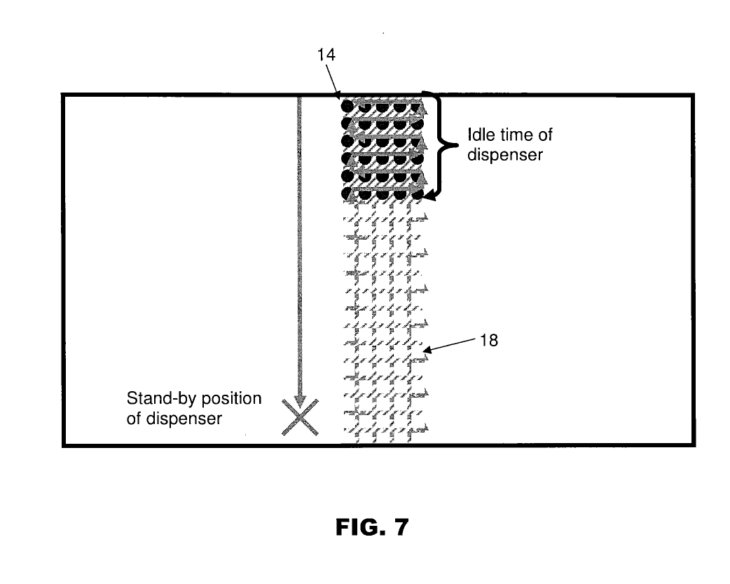

FIG. 7 is a schematic plan view of the leadframe 12 illustrating completion of adhesive dispensation over multiple columns of die pads 14. After the adhesive has been dispensed onto the last die pad 14 of the last row of die pads 14 in the die bonding section located at the first edge of the leadframe 12, the epoxy dispenser 20 moves to a standby position near the second edge of the leadframe 12. It may remain stationary at the standby position until a die 18 has been bonded to every one of the scanned die pads 14 in the die bonding section. Importantly, the steps of pattern recognition of the leadframe 12, dispensing the adhesive and bonding the dice 18 may all take place while maintaining the leadframe 12 at a substantially stationary position. In the prior art, the leadframe 12 is generally indexed to different stations for adhesive dispensation and for die bonding, thus leading to the shortcomings described above.

The substrate conveying device indexes the leadframe 12 relative to the pick-and-place arm 26 once die attachment has been completed at the last row of die pads 14. The cycle of pattern recognition of die pads 14, epoxy dispensation and die attachment is repeated to a second die bonding section of the leadframe 12 which is separate from the die bonding section that has already undergone die bonding, until all the die pads 14 on the leadframe 12 have each received a die 18.

Using the placement pattern recognition system 22 or an additional separate inspection camera, the result of die attachment at the last column of the leadframe 12 can also provide feedback to the pick-and-place system 26 as to the accuracy of die attachment so that adjustment may be made accordingly to improve subsequent die attachment operations.

It should be appreciated that the die bonder 10 in accordance with the preferred embodiment of the invention improves die bonding efficiency. The common region that is selected for dispensing an adhesive and for die bonding reduces the time difference between the dispensing of an adhesive and the attachment of a die to a die pad. This avoids the problem of the adhesive curing before a die is successfully bonded to it. Hence, a substrate with high density die pads may still be able to receive a fast-curing adhesive during die bonding. Furthermore, dispensation of adhesive and die attachment can be carried out successively at almost the same time, which improves the throughput of the entire die bonding process.

Additionally unlike the prior art described above, the die bonder 10 only requires the use of one optical assembly for pattern recognition of the position of the leadframe 12 and for die attachment. No separate optical system to aid the accurate dispensation of adhesive is required. As such, the cost of installing a second optical system for dispensation of adhesive can also be avoided.

The invention described herein is susceptible to variations, modifications and/or addition other than those specifically described and it is to be understood that the invention includes all such variations, modifications and/or additions which fall within the spirit and scope of the above description.

1. A method of bonding semiconductor dice onto a substrate, the method comprising the steps of:
using an optical assembly to perform pattern recognition of a die bonding section of the substrate in which multiple die pads are located so as to identify positions of the multiple die pads simultaneously during the pattern recognition step;
after the pattern recognition of the said die bonding section, dispensing an adhesive with an adhesive dispenser onto at least one of the die pads located in the die bonding section; and
while dispensing the adhesive to further die pads located in the die bonding section, concurrently bonding a die with a pick-and-place arm onto each die pad where the adhesive has already been dispensed.

2. The method as claimed in claim 1, wherein the die pads in the die bonding section form a portion of all the die pads located on the substrate.

3. The method as claimed in claim 2, wherein the die bonding section comprises multiple columns and rows of die pads.

4. The method as claimed in claim 3, wherein the step of pattern recognition further comprises the step of moving the optical assembly from one edge of the substrate to an opposite edge of the substrate parallel to a column of die pads while viewing multiple columns of die pads at the same time.

5. The method as claimed in claim 3, wherein the step of dispensing the adhesive comprises the step of sequentially dispensing adhesive a row at a time to a plurality of columns of die pads in the die bonding section.

6. The method as claimed in claim 2, wherein the die bonding section comprises a single column containing multiple rows of die pads.

7. The method as claimed in claim 6, wherein the step of dispensing the adhesive comprises the step of sequentially dispensing adhesive a row at a time to a single column of die pads a row at a time.

8. The method as claimed in claim 1, wherein the step of bonding a die onto each die pad is conducted in a same sequence as a sequence by which adhesive has been dispensed onto each die pad.

9. The method as claimed in claim 1, further comprising the steps of:
moving the adhesive dispenser to a standby position after the adhesive has been dispensed onto a last die pad in the die bonding section; and
positioning the adhesive dispenser at the standby position until all the die pads in the die bonding section have been bonded with a die each.

10. The method as claimed in claim 1, further comprising the steps of:
after bonding dice onto all the die pads in the die bonding section, using the optical assembly to perform pattern recognition of a second die bonding section of the substrate in which multiple die pads are located so as to identify positions of the multiple die pads simultaneously during a pattern recognition step, the second die bonding section being separate from the said die bonding section;
after the pattern recognition of the second die bonding section, dispensing an adhesive with the adhesive dispenser onto at least one of the die pads located in the second die bonding section; and
while dispensing the adhesive to further die pads located in the second die bonding section, concurrently bonding a die with the pick-and-place arm onto each die pad where the adhesive has already been dispensed.

11. The method as claimed in claim 1, further comprising the step of inspecting the adhesive which has been dispensed using the optical assembly before bonding the die onto the die pad.

12. The method as claimed in claim 1, further comprising the step of inspecting the dice with the optical assembly to check bonding accuracy after the step of bonding the dice.

13. The method as claimed in claim 1, wherein the steps of pattern recognition of the substrate, dispensing the adhesive and bonding the dice all take place while maintaining the substrate at a substantially stationary position.

14. The method as claimed in claim 1, wherein the pick-and-place arm is operative to bond the dice onto positions of the multiple die pads using positional information that had been obtained during the said pattern recognition step.

15. The method as claimed in claim 1, wherein the pick-and-place arm is positioned adjacent to the adhesive dispenser.

16. The method as claimed in claim 1, wherein the optical assembly comprises both a pick-up pattern recognition system and a placement pattern recognition system which are incorporated into the optical assembly.
